(19) United States
(12) Patent Application Publication
(10) Pub. No.: US 2025/0214119 A1
(43) Pub. Date: Jul. 3, 2025

(54) CLEANING METHOD FOR EXHAUST GAS TREATMENT FACILITY

(71) Applicant: KURITA WATER INDUSTRIES LTD., Tokyo (JP)

(72) Inventors: Shingo Harashima, Tokyo (JP); Kazumi Tsukamoto, Tokyo (JP); Takanobu Kimura, Tokyo (JP)

(73) Assignee: KURITA WATER INDUSTRIES LTD., Tokyo (JP)

(21) Appl. No.: 18/851,077

(22) PCT Filed: Mar. 8, 2023
(86) PCT No.: PCT/JP2023/008699

§ 371 Date: Sep. 26, 2024

(30) Foreign Application Priority Data
Mar. 30, 2022 (JP) 2022-055286

(51) Int. Cl. B08B 3/08; B01D 47/06; B08B 3/02; B08B 13/00; H01L 21/67

(52) U.S. Cl. CPC B08B 3/08; B01D 47/06; B08B 3/02; B08B 13/00; B08B 2203/027; H01L 21/67017

(57) ABSTRACT

An exhaust gas treatment facility includes a combustion chamber 1 for applying combustion treatment to exhaust gas, a nozzle for causing water to flow along the inner wall surface of the combustion chamber 1, a water supply line for supplying water to the nozzle, a primary wet scrubbing chamber 11, and a wet scrubber 20, etc. When removing a solid matter from the wet scrubber 20, an alkaline-based cleaning agent solution is injected to a lower water tank 44 from a chemical dispensing device 50, and a circulation pump 23 is operated to sprinkle water from a nozzle 21. Cleaning is ended if the detected pH by pH meters 52, 53 maintains a defined pH for a predetermined time or more.

### TECHNICAL FIELD

The invention relates to a cleaning method for an exhaust gas treatment facility, and more specifically relates to a cleaning method for an exhaust gas treatment facility for treating exhaust gas from a semiconductor manufacturing process, etc.

### RELATED ART

Exhaust gas containing perfluoro compounds, etc., is discharged from manufacturing processes of semiconductors, liquid crystals, LEDs, solar cells, etc. The exhaust gas may contain WF₆, CH₂F₂, Cl₂, BCl₃, F₂, HF, SiH₄, NH₃, PH₃, tetraethoxysilane (TEOS), triethoxysilane (TRIS), TiCl₄, etc. In an exhaust gas treatment facility (detoxifying apparatus) that treats such exhaust gas, after the perfluoro compounds are burned (oxidized) or subjected to a thermal decomposition reaction through combustion, electric heating, plasma, etc., the exhaust gas is scrubbed in a scrubbing chamber incorporated in the apparatus to absorb and remove F₂, etc., in the gas.

As a combustion treatment apparatus of the exhaust gas, a water-cooling combustion-type detoxifying apparatus is provided (Patent Document 1). Such detoxifying apparatus is configured to cause water to flow down along the inner wall surface of the combustion chamber, prevent products of the combustion from being attached to the inner wall surface, and protect the inner wall surface from combustion heat.

A wet scrubber is widely used as a cleaning treatment apparatus of exhaust has (Patent Document 2).

### PRIOR ART DOCUMENT(S)

### Patent Document(s)

Patent Document 1: Japanese Laid-open No. 2003-24741
Patent Document 2: Japanese Unexamined Utility Model Application Publication No. S63-66132

### SUMMARY OF INVENTION

### Technical Problem

In a water-cooling combustion-type detoxifying apparatus, deposits may be formed inside the detoxifying apparatus, pipes, etc., and a process is required to stop the detoxifying apparatus and remove the deposits. Examples of the deposits may include silica and tungsten solid matters. However, other solid matters may also be formed.

In the conventional detoxifying apparatuses, if solid matters are formed, the apparatus is stopped, and the operator performs a cleaning process, which is labor-, cost-, and time-consuming.

Patent Document 2 describes to provide a jet spray nozzle at the bottom part in the wet scrubber to spray cleaning water upward onto a porous plate in the scrubber and physically peel off sediments and deposits. However, the inside of the scrubber cannot be cleaned sufficiently.

An objective of the invention is to provide a cleaning method of an exhaust gas treatment facility capable of sufficiently removing solid matters, such as sediments, deposits, etc., in the exhaust gas treatment facility within a short time.

### Solution to Problem

A cleaning method of an exhaust gas treatment facility according to the invention is a cleaning method of an exhaust gas treatment facility for treating exhaust gas from an electronic component manufacturing process, and is a cleaning method of a wet exhaust gas treatment facility. The cleaning method includes: supplying and circulating a cleaning liquid that dissolves and/or disperses solid matters deposited and/or sedimented on a cleaning target of the exhaust gas treatment facility; and managing ending of cleaning and/or additionally injecting a cleaning component to the cleaning liquid based on a measurement value of a water quality index value including at least one of pH, conductivity, oxidation reduction potential, and turbidity of the cleaning liquid.

According to an aspect of the invention, in the cleaning method, the exhaust gas treatment facility has: a detoxifying apparatus, performing a treatment that decomposes exhaust gas by using heat; and a wet scrubber, to which gas from the detoxifying apparatus is guided, and the cleaning method of the exhaust gas treatment facility is a method for cleaning the wet scrubber.

According to an aspect of the invention, the wet scrubber has: a lower sink; and a water sprinkling mechanism, to which water is supplied and circulated from the lower sink by using a circulation pump, the cleaning method of the exhaust gas treatment facility includes: a process of adding a cleaning agent aqueous solution to the lower sink; and a process of supplying water in the lower sink to which the cleaning agent aqueous solution is added to the water sprinkling mechanism, and the measurement value of the water quality index value is a measurement value of at least one of water in the lower sink, water supplied from the lower sink to the water sprinkling mechanism, and water flowing out from the lower sink.

According to an aspect of the invention, the water quality index value is pH, when cleaning starts, the cleaning agent aqueous solution is added so that the pH is at a predetermined value or more, addition of the cleaning agent aqueous solution is stopped in a case where the pH is at the predetermined value or more, and after the cleaning agent aqueous solution, cleaning is ended in a case where the pH is maintained at the predetermined value or more for a predetermined time or more.

According to an aspect of the invention, the wet scrubber includes a mist catcher, an underwater pump is provided in the lower sink, and a water sprinkler is provided on an upper side of the mist catcher, and water in the lower sink is supplied to the water sprinkler by using the underwater pump to clean the mist catcher and an inside of the wet scrubber lower than the mist catcher.

### Effects of Invention

According to the invention, solid matters in an exhaust gas treatment facility can be sufficiently dissolved and/or dispersed and removed by using a cleaning agent within a short time. In the case where the invention is applied to a manufacturing facility of semiconductors, etc., the operation efficiency of manufacturing process machines of semiconductors can be facilitated, and the productivity of semiconductors etc., is facilitated.

### BRIEF DESCRIPTION OF DRAWINGS

FIG. 1 is a diagram illustrating a configuration of a detoxifying facility.

FIG. 2 is a diagram illustrating a configuration of a wet scrubber.

FIG. 3 is a graph illustrating test results.

### DESCRIPTION OF EMBODIMENTS

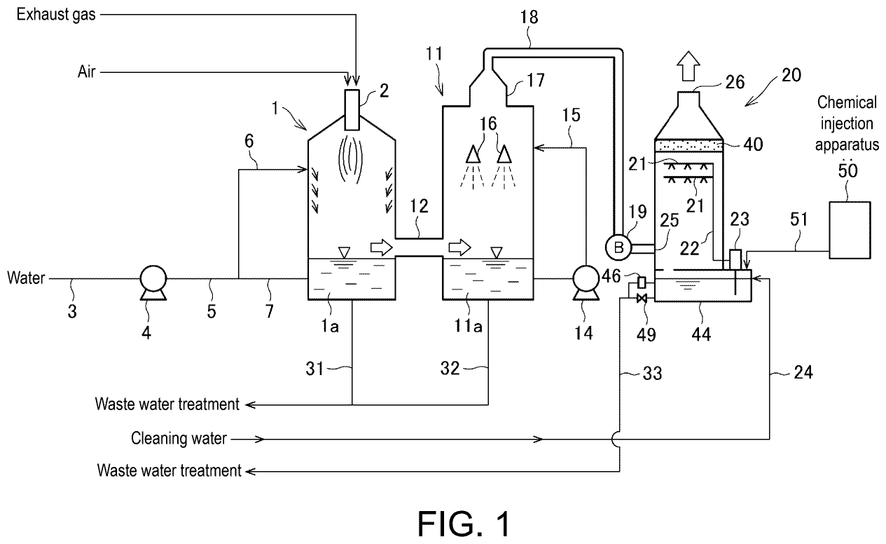

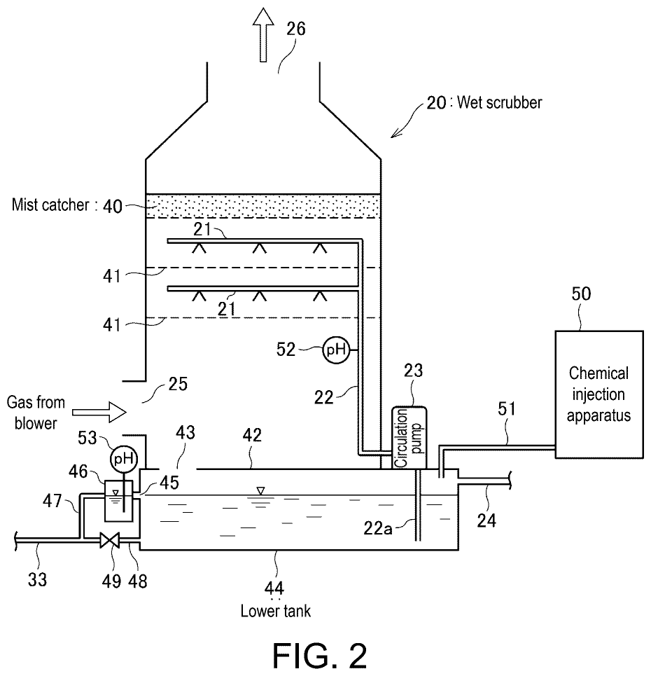

In the following, an example of a detoxifying facility to which a method according to an embodiment is applied is described with reference to FIGS. 1 and 2.

In the detoxifying apparatus, exhaust gas from a semiconductor manufacturing process and air from a blower are supplied to a burner 2 provided at the upper part of a tower-shaped combustion chamber 1, and the exhaust gas is subjected to a combustion treatment in the combustion chamber 1.

The gas generated in an electronic component manufacturing process is suitable as the exhaust gas. Particularly, gas containing WF₆ is suitable as the exhaust gas. The gas may also contain silane (SiH₄, Si₂H₆, SiH₂Cl₂, etc.,) or other gas components other than silane (B₂H₆, PH₃, NH₃, N₂O, H₂, H₂Se, GeHe, AsH₃, CH₄, C₂H₄, CO, Cl₂, F₂, ClF₃, NF₃, CH₂F₂, NO, O₂, CF₄, C₄F₈, C₅F₈, CHF₃, etc.)

A nozzle (not shown) is provided to cause water to flow along the inner wall surface of the combustion chamber 1, and water is supplied to the nozzle through a water supply line. The water flowing from the nozzle flows down like a water film through the inner wall surface of the combustion chamber 1, and the inner wall surface is protected from the heat of combustion. With the water flowing like a water film through the inner wall surface of the combustion chamber 1, water soluble components in the combustion gas are absorbed, and micro-particles are captured. In addition, the gas temperature decreases.

The water flowing down through the inner wall surface is accumulated in a pit 1a in the bottom part of the combustion chamber.

The water supply line to the nozzle has a pipe 3, a pump 4, a pipe 5, and pipes 6, 7 branched from the pipe 5. The pipe 6 is connected to the nozzle, the pipe 7 is provided to supply water to the pit 1a of the bottom part of the combustion chamber 1.

A primary scrubbing chamber 11 is provided in adjacency with the combustion chamber 1. The lower part of the combustion chamber 1 and the lower part of the primary scrubbing chamber 11 are in communication through a duct 12. The gas from the combustion chamber 1 is guided into the primary scrubbing chamber 11 via the duct 12 and rises in the primary scrubbing chamber 11.

A portion of the water in the pit 1a of the combustion chamber 1 flows out to a pit 11a of the primary scrubbing chamber 11 due to overflow through the duct 12. A portion of the water in the pit 1a of the combustion chamber 1 may also be transferred to the pit 11a via a water transfer pipe different from the duct 12.

The water of the pit 11a at the bottom part of the primary scrubbing chamber 11 is sprinkled by a water sprinkler 16 via a pump 14 and a pipe 15. The gas that has risen in the primary scrubbing chamber 11 comes into contact with the water sprinkled from the water sprinkler 16, and the water soluble components or micro-particles in the gas are absorbed or captured by water.

The gas that has passed through the primary scrubbing chamber 11 is guided to a wet scrubber 20 via a gas inlet 25 through a duct 18 and a blower 19 from a gas outlet 17.

Water at the bottom part inside the wet scrubber 20 is supplied to a nozzle 21 (water sprinkling mechanism) at the upper part inside the wet scrubber 20 through a circulation pump 23 and a pipe 22. After the gas comes into contact with the water sprinkled from the nozzle 21 and the water soluble components or micro-particles are absorbed or captured by water, the gas flows out from an outlet 26. Gas cleaning water is supplemented to the wet scrubber through a pipe 24.

The water at the bottom parts of the combustion chamber 1, the primary scrubbing chamber 11, and the wet scrubber 20 is taken out via pipes 31, 32, 33 and supplied to a wastewater treatment facility (not shown) to be treated.

The detailed configuration of the wet scrubber 20 is as shown in FIG. 2. A mist catcher 40 is provided at the upper part inside the wet scrubber 20. A grating 41 is provided on the lower side of the nozzle 21.

A portion of a lower sink 44 of the wet scrubber 20 projects toward the lateral side, and the pump 23 is provided on the upper side thereof. The water inside the lower sink 44 is suctioned by the pump 23 through a pipe 22a, and is supplied to the nozzle 21 via the pipe 22.

The water sprinkled from the nozzle 21 drops onto an intermediate plate 42 and drops into the lower sink 44 through a water drop hole 43 provided at the intermediate plate 42.

The gas inlet 25 is provided on a wet scrubber side wall surface upper of the intermediate plate 42.

The pipe 24 is connected to the lower sink 44. An overflow port 45 is provided at an upper position on the side surface of the lower sink 44. When the water level inside the lower sink 44 is higher than the overflow port 45, the water in the lower sink 44 flows to a relay tank 46 from the overflow port 45, and flows from the relay tank 46 to the pipe 33 via the pipe 47.

A pipe 48 is provided for the bottom part inside the lower sink 44 and the pipe 47 to communicate, and a valve 49 is provided at the pipe 48. The valve 49 is opened only for draining water from the lower water tank 44, and is otherwise closed.

An aqueous solution of the cleaning agent can be injected from a chemical injection apparatus 50 to the lower sink 44 via a pipe 51. The chemical injection apparatus 50 has a tank for storing the aqueous solution of the cleaning agent, a chemical injection pump, and a control circuit for controlling the chemical injection pump.

In the embodiment, pH meters 52, 53 are respectively provided at the pipe 22 and the relay tank 46, and the detection signals of the pH meters 52, 53 are transmitted to the control circuit.

To perform removal and cleaning of the solid matters of the wet scrubber 20, in a state in which the circulation pump 23 is operating, a cleaning start instruction signal is input to the control circuit after the blower 19 is stopped. When applied with such signal, the control circuit starts the chemical injection pump and performs chemical injection until the average of the detected pHs of the pH meters 52, 53 (or the detection value of at least one of the pH meters) reaches or exceeds a predetermined pH (an alkaline pH value selected between 8 and 14, particularly 11 to 14), and stops chemical injection if the average (or detection value) reaches or exceeds the predetermined pH. When the average of the detected pHs drops below the predetermined pH, the chemical injection starts again, and the chemical injection stops if the average reaches or exceeds the predetermined pH.

Through the chemical injection of the aqueous solution of the cleaning agent to the wet scrubber 20 by using the chemical injection apparatus 50, the water ejected from the nozzle 21 becomes water that contains the cleaning agent, and solid matters, such as deposits or sediments, in the wet scrubber 20 are dissolved and/or dispersed. When a large amount of the solid matters remains, if the chemical injection stops, the pHs detected by the pH meters 52, 53 decrease. However, when the dissolution and/or dispersion of the solid matters is performed sufficiently, even if the chemical injection stops, the detected pHs hardly drop.

Therefore, when the average of the detected pHs remains equal to or more than the predetermined pH even if the chemical injection stops and a predetermined time (e.g., a time selected from 1 to 24 hours, particularly 1 to 6 hours) has passed, it is determined that the dissolution and/or dispersion of the solid matters has been performed sufficiently, and the chemical injection stops. In addition, the circulation pump 23 stops, and the valve 49 opens to discharge the cleaning wastewater inside the lower sink 44. Then, after the valve 49 is closed and gas cleaning water is injected into the lower sink 44 from the pipe 24, the circulation pump 23 and the blower 19 are operated, and the treatment using the wet scrubber 20 starts again.

In the embodiment, although the cleaning of the wet scrubber 20 is performed in a state in which the exhaust gas treatment is stopped, the cleaning may also be performed in a state in which the exhaust gas treatment continues. In addition, cleaning may be performed periodically, and may also be performed in a case where solid matters are attached and the gas discharge capability or the exhaust gas treatment performance deteriorates.

In this way, according to the cleaning method, the solid matters of the wet scrubber 20 can be dissolved and removed sufficiently within a short time by using the cleaning agent aqueous solution, the operation time can be reduced, and the operation labor and cost can be decreased.

In addition, in a mode in which cleaning is performed in the state where the exhaust gas treatment continues, the operation stoppage of the semiconductor manufacturing process that comes together with the stoppage of the exhaust gas treatment process is prevented, and the productivity increases.

As the cleaning agent, alkali agents, such as inorganic alkali agents like sodium hydroxide, potassium hydroxide, ammonia, and sodium metasilicate, and organic alkali agents like choline and TMAH are suitable. However, the invention is not limited thereto. In addition to alkali agents, examples of the cleaning agent may also include silica scale cleaning agents, dissolution aids (hydrogen peroxide, EDTA, polyphosphoric acid, etc.), calcium scale inhibitors, slime control agents (dichloroglyoxime, 2,2-dibromo-2-nitroethanol, 2,2-dibromo-3-nitrilopropionamide, chlorosulfamic acid, bis-1,4-bromoacetoxy-2-butene, ametryn, 5-chloro-2-methyl-4-isothiazolin-3-one), etc. Alkali agents may also be waste alkali from an electronic component factory, etc.

The embodiment is merely an example of the invention, and the invention may also be embodied in other forms than those described above. For example, although the pH meters are disposed at two positions in the embodiment, the pH meters may also be disposed at one position or three or more positions.

In the embodiment, although the chemical injection is controlled based on pHs, the invention is not limited thereto. Chemical injection may also be controlled based on at least one of pH, conductivity, oxidation reduction potential and turbidity.

In the embodiment, the aqueous solution of the cleaning agent is caused to flow out from the nozzle 21 by the circulation pump 23. However, it may also be that an underwater pump is provided in the lower sink 44, the water sprinkler is provided on the upper side of the mist catcher 40, the water discharged from the underwater pump is supplied to the water sprinkler via a hose to be sprinkled, and the solid matters in the mist catcher 40 or a region on the lower side thereof are dissolved and/or dispersed.

The underwater pump can be disposed in the lower sink 44 via a lower sink inspection hatch provided in the vicinity of the circulation pump 23. In addition, the hose can be drawn out of the wet scrubber 20 via the lower sink inspection hatch, and can be drawn into the upper part in the wet scrubber 20 via an inspection window (not shown) or the outlet 26 on a side surface of the wet scrubber 20.

Although the embodiment removes the solid matters of the wet scrubber 20, other cleaning targets, such as the primary scrubbing chamber 11 or the blower 19, may also be cleaned by using the cleaning agent aqueous solution. In such case as well, the cleaning liquid is circulated and supplied to the cleaning target, the pH of the cleaning agent aqueous solution flowing from the cleaning target is measured, and the cleaning agent is added when the pH is lower than the predetermined value. In addition, when pH is maintained at the predetermined value for a predetermined time or longer, it is suitable to end the cleaning.

In the embodiment, the detoxifying apparatus is of a “combustion type”. However, the invention is not limited thereto. The apparatus may also perform detoxification by using heat such as electric heating or plasma heating.

### EXAMPLES

A dissolution test of solid matters (sediments collected from the scrubber) by using alkali was conducted.

### <Test Method>

Solid matters (deposits collected from a scrubber installed at a stage downstream of a detoxifying apparatus in a semiconductor manufacturing process) were added to 100 mL of a 1 wt % choline solution to render 0.5 wt %, 1 wt %, 2 wt %, 3 wt %, or 5 wt %, thereby giving Sample Nos. 1 to 5. The respective solutions were stirred by using a stirrer, and the changes of pHs and appearances (pictures were taken from the bottom of the beaker) through time were measured and observed. Table 1 indicates the test conditions of various samples. The total amount of the solution was 100 mL, so the added amounts of solid matters directly indicate the concentrations of wt %.

TABLE 1
Test condition

| | | |
|---|---|---|
| Solid matter | Choline | Solution amount |

| Sample | [g] | Measured value | [%] | [ml] |
|---|---|---|---|---|
| \textcircled{1} | 0.5 | 0.5107 | 1 | 100 |
| \textcircled{2} | 1 | 1.0068 | 1 | 100 |
| \textcircled{3} | 2 | 2.0069 | 1 | 100 |
| \textcircled{4} | 3 | 3.0269 | 1 | 100 |
| \textcircled{5} | 5 | 4.9671 | 1 | 100 |

### <Results>

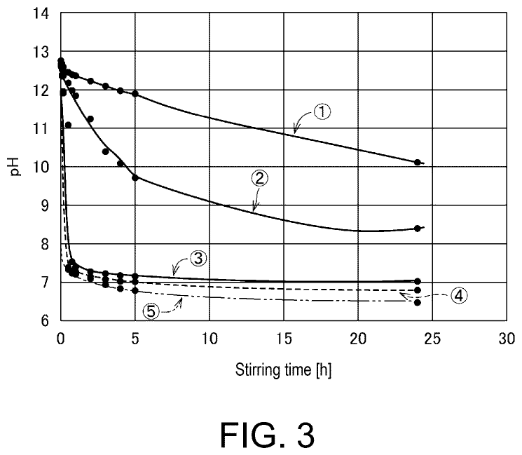

For the respective samples, the results of stirring and measuring pHs through time are indicated in Table 2. In addition, the results are graphed shown in FIG. 3.

TABLE 2
Changes of pHs of respective samples through stirring time

| | |
|---|---|
| Stirring time | pH |

| min. | hour | \textcircled{1} | \textcircled{2} | \textcircled{3} | \textcircled{4} | \textcircled{5} |
|---|---|---|---|---|---|---|
| 0 | 0 | 12.76 | 12.76 | 12.76 | 12.76 | 12.76 |
| 1 | 0.01667 | 12.68 | 12.68 | 12.66 | 12.63 | 12.60 |
| 5 | 0.08333 | 12.67 | 12.60 | 12.53 | 12.36 | 12.39 |
| 10 | 0.16667 | 12.59 | 12.50 | 12.37 | 11.96 | 11.92 |
| 30 | 0.5 | 12.46 | 12.18 | 11.08 | 7.38 | 7.33 |
| 45 | 0.75 | 12.40 | 11.99 | 7.53 | 7.29 | 7.23 |
| 60 | 1 | 12.37 | 11.85 | 7.39 | 7.27 | 7.20 |
| 120 | 2 | 12.23 | 11.24 | 7.27 | 7.14 | 7.09 |
| 180 | 3 | 12.10 | 10.39 | 7.22 | 7.07 | 6.93 |
| 240 | 4 | 11.98 | 10.08 | 7.17 | 7.02 | 6.83 |
| 300 | 5 | 11.90 | 9.71 | 7.15 | 7.01 | 6.78 |
| 1440 | 24 | 10.11 | 8.40 | 7.02 | 6.79 | 6.47 |

As shown in FIG. 3, the pHs of the solutions (Sample Nos. 3, 4, 5) in which the solid matter concentrations were 2 wt % to 5 wt % dropped to 7.2 to 7.6 after the solutions were stirred for 30 minutes to 45 minutes, and then the PHs became stable. This indicates that the amount of solid matters was large relative to the amount of choline. From the results of appearance observation as well, it is clear that undissolved solid matters remained in Sample Nos. 3 to 5. Meanwhile, in the solutions (Sample Nos. 1, 2) in which the solid matter concentrations were 0.5 wt % to 1 wt %, pHs decreased through stirring and became stable in the alkaline region after the solutions were stirred for 24 hours. From the results of appearance observation, it is also shown that the solid matters were substantially dissolved after Sample No. 1 was stirred for five hours and Sample No. 2 was stirred for 24 hours.

Accordingly, it is necessary for the pH of the cleaning solution to be 8 or more, and, to sufficiently dissolve solid matters within a short time, it is necessary to for the pH to be 10 or more. Also, it is suggested that the cleaning effect can be verified through pH changes.

### <Inspection>

From the test results, three points as follows are attained:
pH decreases through the dissolution of solid matters.
when the solid matters remain, pH is stable in the neutral region.
the higher the pH, the better the effect of dissolving solid matters.

From the above, under the consideration of cleaning solid matters at the site, a control method as follows is considered: alkaline is additionally injected when pH reaches neutral, and the solid matters are determined as dissolved if the pH is stable in the alkaline region for the time being. Also, since the higher the concentration of the alkaline the higher the reaction speed, if cleaning within a short time is required, it is considered that cleaning should be performed with alkaline with a concentration same as or higher than the concentration of solid matters.

Although the invention has been described in detail with reference to specific embodiments, it will be apparent to those skilled in the art that various modifications can be made without departing from the spirit and scope of the invention.

This application is based on Japanese Patent Application No. 2022-055286 filed on Mar. 30, 2022, the entirety of which is incorporated by reference.

### REFERENCE SIGNS LIST

1: Combustion chamber;
2: Burner;
4: Pump;
11: Primary scrubbing chamber;
20: Wet scrubber;
21: Nozzle;
23: Circulation pump;
40: Mist catcher;
44: Lower sink;
46: Relay tank;
50: Chemical injection apparatus;
52, 53: pH meter.

1. A cleaning method of an exhaust gas treatment facility for treating exhaust gas from an electronic component manufacturing process, which is a cleaning method of a wet exhaust gas treatment facility, the cleaning method comprising:
supplying and circulating a cleaning liquid that dissolves and/or disperses solid matters deposited and/or sedimented on a cleaning target of the exhaust gas treatment facility; and
managing ending of cleaning and/or additionally injecting a cleaning component to the cleaning liquid based on a measurement value of a water quality index value comprising at least one of pH, conductivity, oxidation reduction potential, and turbidity of the cleaning liquid.

2. The cleaning method as claimed in claim 1, wherein the exhaust gas treatment facility has: a detoxifying apparatus, performing a treatment that decomposes exhaust gas by using heat; and a wet scrubber, to which gas from the detoxifying apparatus is guided, and
the cleaning method of the exhaust gas treatment facility is a method for cleaning the wet scrubber.

3. The cleaning method as claimed in claim 2, wherein the wet scrubber has: a lower sink; and a water sprinkling mechanism, to which water is supplied and circulated from the lower sink by using a circulation pump,
the cleaning method of the exhaust gas treatment facility comprises: a process of adding a cleaning agent aqueous solution to the lower sink; and a process of supplying water in the lower sink to which the cleaning agent aqueous solution is added to the water sprinkling mechanism, and
the measurement value of the water quality index value is a measurement value of at least one of water in the lower sink, water supplied from the lower sink to the water sprinkling mechanism, and water flowing out from the lower sink.

4. The cleaning method as claimed in claim 3, wherein the water quality index value is pH,
when cleaning starts, the cleaning agent aqueous solution is added so that the pH is at a predetermined value or more,
addition of the cleaning agent aqueous solution is stopped in a case where the pH is at the predetermined value or more, and
after the cleaning agent aqueous solution, cleaning is ended in a case where the pH is maintained at a predetermined value or more for a predetermined time or more.

5. The cleaning method as claimed in claim 3, wherein the wet scrubber comprises a mist catcher,
an underwater pump is provided in the lower sink, and a water sprinkler is provided on an upper side of the mist catcher, and
water in the lower sink is supplied to the water sprinkler by using the underwater pump to clean the mist catcher and an inside of the wet scrubber lower than the mist catcher.

6. The cleaning method as claimed in claim 4, wherein the wet scrubber comprises a mist catcher,
an underwater pump is provided in the lower sink, and a water sprinkler is provided on an upper side of the mist catcher, and
water in the lower sink is supplied to the water sprinkler by using the underwater pump to clean the mist catcher and an inside of the wet scrubber lower than the mist catcher.
